(19) United States
(12) Patent Application Publication
(10) Pub. No.: US 2018/0198046 A1
(43) Pub. Date: Jul. 12, 2018

(54) LIGHT EMITTING PACKAGE

(71) Applicant: SAMSUNG ELECTRONICS CO., LTD., Suwon-si (KR)

(72) Inventors: KyungWook HWANG, Hwaseong-si (KR); Yuri JUNG, Seoul (KR); Mingyeong GWON, Suwon-si (KR); Eunjoo SHIN, Seoul (KR)

(21) Appl. No.: 15/863,448

(22) Filed: Jan. 5, 2018

(30) Foreign Application Priority Data
Jan. 6, 2017 (KR) 10-2017-0002428

(51) Int. Cl. H01L 33/60; H01L 33/50; H01L 33/48

(52) U.S. Cl. CPC H01L 33/60; H01L 33/486; H01L 33/505

(57) ABSTRACT

A light emitting package includes a light emitting device having an electrode disposed on a bottom surface of the light emitting device, a transparent substrate covering a top surface and a sidewall of the light emitting device, and a reflective structure provided adjacent sidewalls of the light emitting device and having a refractive index different from that of the transparent substrate. The electrode is exposed by the transparent substrate and the reflective structure.

### CROSS-REFERENCE TO RELATED APPLICATION

Korean Patent Application No. 10-2017-0002428, filed on Jan. 6, 2017, in the Korean Intellectual Property Office, and entitled: Light Emitting Package, is incorporated by reference herein in its entirety.

### BACKGROUND

### 1. Field

Embodiments relate to a light emitting package and, more particularly, to a light emitting package including a reflective structure.

### 2. Description of the Related Art

Light emitting devices such as a light emitting diode may emit light using a light emitting material included therein. In a light emitting device, electrons and holes may be recombined with each other in a junction semiconductor to generate energy and the energy may be converted into light. These light emitting devices are widely used in various electronic devices (e.g., illuminators, display devices, light sources, and so forth) and are still being studied. To use the light emitting devices in the electronic devices, the light emitting devices may be packaged as light emitting packages. As application fields of light emitting devices increases, improved light extraction efficiency and reliability of light emitting packages is demanded.

### SUMMARY

In an aspect, a light emitting package may include a light emitting device having an electrode disposed on a bottom surface, a transparent substrate covering a top surface and sidewalls of the light emitting device, and a reflective structure adjacent sidewalls of the light emitting device and having a refractive index different from that of the transparent substrate. The electrode may be exposed by the transparent substrate and the reflective structure.

In an aspect, a light emitting package may include a light emitting device including an electrode provided on a bottom surface, a transparent substrate covering a top surface and a sidewall of the light emitting device and having a trench extending from a first surface of the transparent substrate into the transparent substrate, and a reflective structure provided in the trench and having a refractive index different from that of the transparent substrate. The trench may have a sidewall inclined with respect to the first surface of the transparent substrate. The reflective structure may be disposed on the sidewall of the light emitting device, and the electrode may be exposed by the reflective structure.

### BRIEF DESCRIPTION OF THE DRAWINGS

Features will become apparent to those of ordinary skill in the art by describing in detail exemplary embodiments with reference to the attached drawings in which:

FIG. 1A illustrates a plan view of a light emitting package according to some embodiments.

FIG. 1B illustrates a cross-sectional view taken along a line A-B of FIG. 1A.

FIG. 1C illustrates a cross-sectional view of a light emitting device according to some embodiments.

FIG. 1D illustrates a cross-sectional view of a light emitting package according to some embodiments.

FIGS. 2A to 2D illustrate cross-sectional views of second reflective structures according to some embodiments.

FIGS. 3 to 9 illustrate cross-sectional views of light emitting packages according to some embodiments.

FIG. 10 illustrates a cross-sectional view of a light emitting apparatus according to some embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

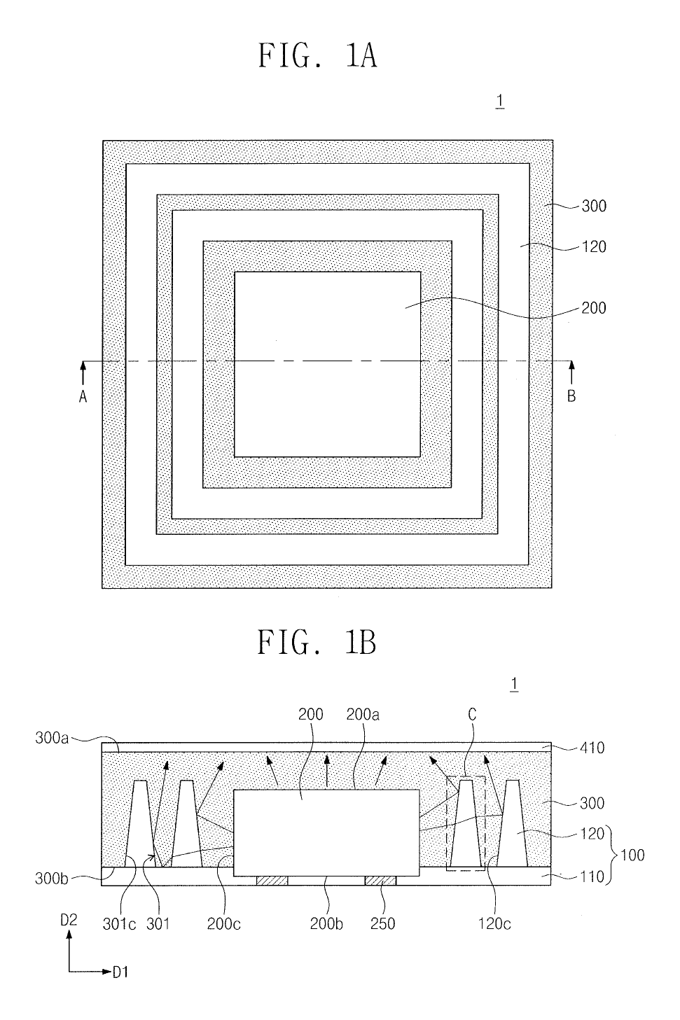

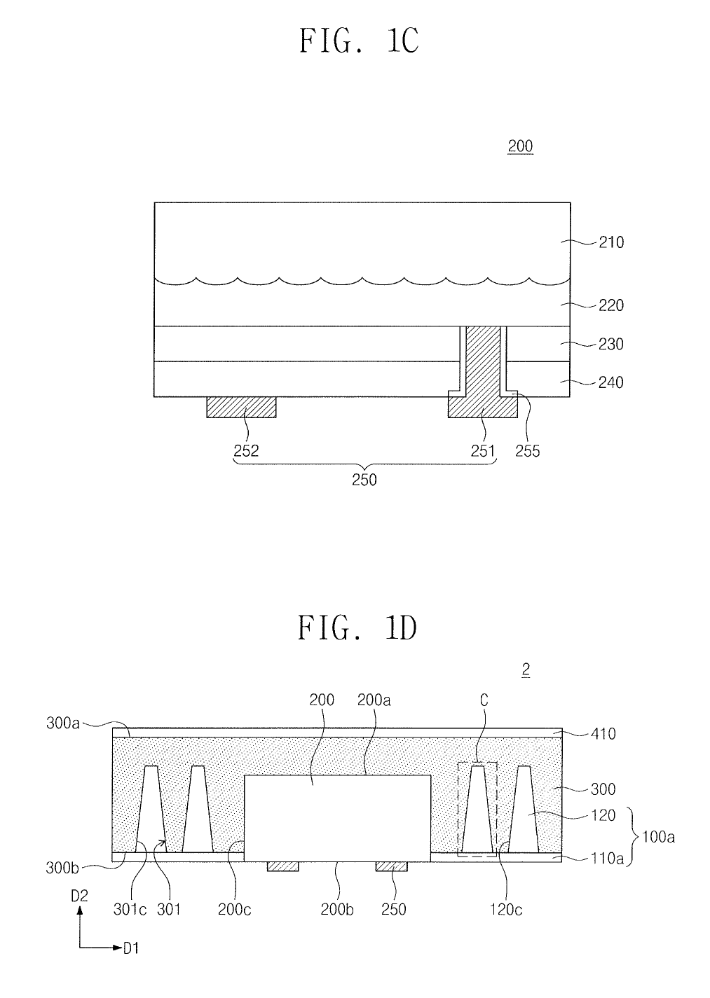

FIG. 1A illustrates a plan view of a light emitting package according to some embodiments. FIG. 1B illustrates a cross-sectional view taken along a line A-B of FIG. 1A. FIG. 1C illustrates a cross-sectional view of a light emitting device according to some embodiments.

Referring to FIGS. 1A and 1B, a light emitting package 1 may include a light emitting device 200, a transparent substrate 300, and a reflective structure 100. The light emitting package 1 may be a chip scale package. The light emitting device 200 may have a top surface 200a, a bottom surface 200b, and sidewalls 200c. The bottom surface 200b of the light emitting device 200 may be opposite to the top surface 200a thereof and connected thereto by the sidewalls 200c. The light emitting device 200 may include an electrode 250. The electrode 250 may be disposed on the bottom surface 200b of the light emitting device 200. In the present specification, spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. Hereinafter, the light emitting device 200 will be described in more detail with reference to FIG. 1C.

Referring to FIG. 1C, the light emitting device 200 may include a growth substrate 210, a first conductivity type semiconductor layer 220, an active layer 230, a second conductivity type semiconductor layer 240, a first electrode 251, and a second electrode 252. The growth substrate 210 may be transparent. The growth substrate 210 may have an uneven portion, e.g., on a bottom surface of the growth substrate 210. In other words, the bottom surface of the growth substrate 210 may be uneven. Thus, light extraction efficiency of the light emitting device 200 may be improved.

The first conductivity type semiconductor layer 220, the active layer 230, and the second conductivity type semiconductor layer 240 may be sequentially stacked on the bottom surface of the growth substrate 210 in that order along a second direction D2. The first conductivity type semiconductor layer 220 may include gallium nitride (GaN) doped with N-type dopants. A buffer layer may further be disposed between the growth substrate 210 and the first conductivity type semiconductor layer 220. The buffer layer may relax stress caused by lattice mismatch between the growth substrate 210 and the first conductivity type semiconductor layer 220.

The active layer 230 may include a material having a multi-quantum well (MQW) structure in which quantum well layers and quantum barrier layers are alternately stacked. For example, the active layer 230 may include gallium nitride (GaN) layers and indium gallium nitride (InGaN) layers which are alternately stacked. The second conductivity type semiconductor layer 240 may include gallium nitride (GaN) doped with P-type dopants.

The electrode 250 may include the first electrode 251 and the second electrode 252. The first electrode 251 may be on a bottom surface of the second conductivity type semiconductor layer 240, e.g., a surface furthest from the growth substrate 210. The first electrode 251 may penetrate the second conductivity type semiconductor layer 240 and the active layer 230 along the second direction D2 so as to be electrically connected to the first conductivity type semiconductor layer 220. An insulating layer 255 may be between the first electrode 251 and the second conductivity type semiconductor layer 240 and between the first electrode 251 and the active layer 230. The second electrode 252 may be disposed on the bottom surface of the second conductivity type semiconductor layer 240 and may be electrically connected to the second conductivity type semiconductor layer 240. The first and second electrodes 251 and 252 may include a metal or a transparent conductive oxide. Electrical signals applied to the first and second electrodes 251 and 252 may be transmitted to the active layer 230. Electron-hole recombination may occur in the active layer 230 to generate light.

Referring again to FIGS. 1A and 1B, the transparent substrate 300 may cover the top surface 200a and the sidewalls 200c of the light emitting device 200. The transparent substrate 300 may not cover the bottom surface 200b of the light emitting device 200 and may expose the electrode 250. The transparent substrate 300 may include glass, sapphire, silicone, or resin.

The transparent substrate 300 may have a trench 301. The trench 301 may extend along the second direction D2 from a first surface of the transparent substrate 300 into the transparent substrate 300. The first surface of the transparent substrate 300 may be a bottom surface 300b of the transparent substrate 300. The bottom surface 300b of the transparent substrate 300 may be parallel to a first direction D1. The trench 301 may have inclined sidewalls 301c. For example, the sidewalls 301c of the trench 301 may be inclined with respect to the bottom surface 300b of the transparent substrate 300, e.g., at an obtuse angle.

Light may be emitted from the top surface 200a and the sidewalls 200c of the light emitting device 200. The light may be emitted to the outside through a top surface 300a of the transparent substrate 300. In other words, the light may be emitted from a top surface of the light emitting package 1. The light emitted from the top surface of the light emitting package 1 may be variously used. As the amount of the light emitted from the top surface of the light emitting package 1 is increased, the light extraction efficiency of the light emitting package 1 may be improved.

The reflective structure 100 may include a first reflective structure 110 and a second reflective structure 120. The first reflective structure 110 may be a reflective layer provided on the bottom surface 300b of the transparent substrate 300. The first reflective structure 110 may cover the bottom surface 200b of the light emitting device 200 but may not cover a bottom surface of the electrode 250. The first reflective structure 110 may be non-conductive. The first reflective structure 110 may have a refractive index different from that of the transparent substrate 300.

The light generated from the light emitting device 200 may be reflected at an interface between the first reflective structure 110 and the transparent substrate 300, and the reflected light may travel to the top surface of the light emitting package 1. In some embodiments, the first reflective structure 110 may include an organic material and particles dispersed in the organic material. The particles may have a refractive index different from that of the organic material. For example, the particles may include an inorganic material such as SiOₓ, MgFₓ, SiCₓ, TiOₓ, HfOₓ, TaₓO_{y}, or SiN (where ‘x’ and ‘y’ are constants). The light may be further reflected at interfaces between the organic material and the particles. In other embodiments, the first reflective structure 110 may include an organic material and fluorescent particles dispersed in the organic material. In still other embodiments, the first reflective structure 110 may include a plurality of layers. Adjacent ones of the plurality of layers may have different refractive indexes from each other. In this case. the first reflective structure 110 may have a distributed Bragg reflective (DBR) structure.

The second reflective structure 120 may be provided on the first reflective structure 110. The second reflective structure 120 may be provided in the trench 301. The second reflective structure 120 may be provided adjacent sidewalls 200c of the light emitting device 200 along the first direction D1, e.g., with only the transparent substrate 300 there between, and may extend further along the second direction than the sidewalls 200c, e.g., may be closer to the top surface 300a of the transparent substrate 300 than the top surface 200a of the light emitting device 200.

The second reflective structure 120 may be transparent. The second reflective structure 120 may have a refractive index different from that of the transparent substrate 300. In some embodiments, the second reflective structure 120 may include silicone or resin. In certain embodiments, the second reflective structure 120 may be a cavity defined by the first reflective structure 110 and the transparent substrate 300. The cavity may be a space in which solids and liquids are not provided. For example, the second reflective structure 120 may be in a vacuum or may be filled with a gas, e.g., air. The gas may have a refractive index different from that of the transparent substrate 300. As illustrated in FIG. 1B, light emitted from the sidewalls 200c of the light emitting device 200 may be reflected at an interface between the second reflective structure 120 and the transparent substrate 300. Even though the light is reflected toward the bottom surface 300b of the transparent substrate 300, the light may be reflected again toward the top surface of the light emitting package 1 by the first reflective structure 110.

The second reflective structure 120 may have a shape corresponding to a shape of the trench 301. The second reflective structure 120 may have sidewalls 120c. The sidewalls 120c of the second reflective structure 120 may be inclined with respect to the bottom surface 300b of the transparent substrate 300, e.g., at the obtuse angle. The sidewalls 120c of the second reflective structure 120 may extend in a direction inclined with respect to the first direction D1. The transparent substrate 300 may cover the sidewalls 120c of the second reflective structure 120. A gradient of the sidewalls 120c of the second reflective structure 120 may be adjusted to allow the light to be reflected toward the top surface of the light emitting package 1.

Unlike FIG. 1B, the second reflective structure 120 may penetrate the transparent substrate 300, e.g., fully extend along the second direction D2 along the transparent substrate 300 such that a top surface of the second reflective structure 120 may be disposed at substantially the same level as the top surface 300a of the transparent substrate 300. Hereinafter, the second reflective structure 120 will be described in more detail.

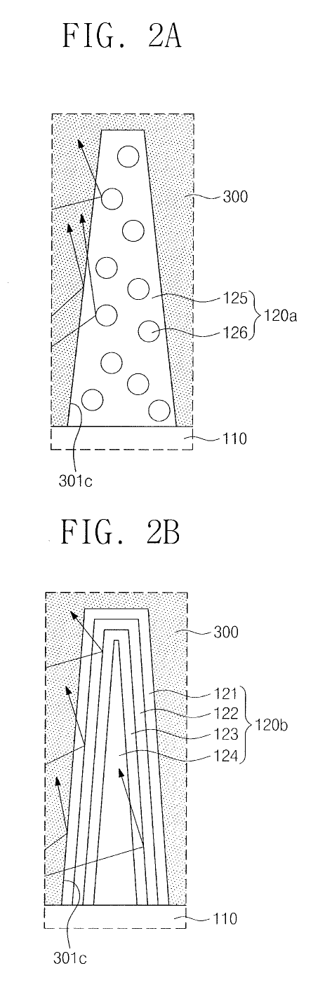

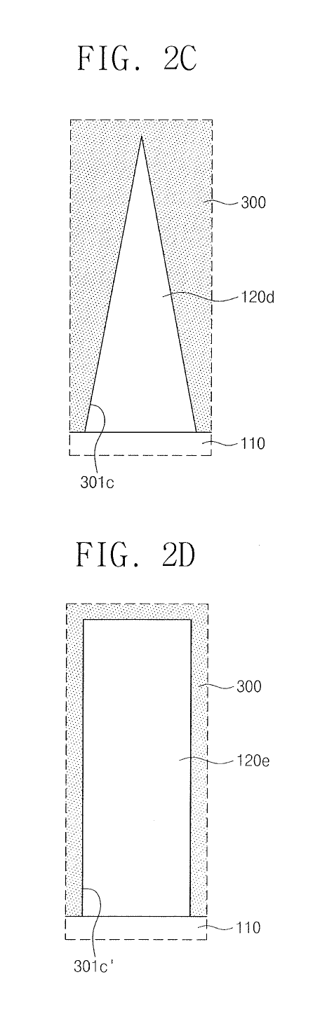

FIGS. 2A to 2D are enlarged views corresponding to region ‘C’ of FIG. 1D, and illustrate second reflective structures according to some embodiments.

Referring to FIG. 2A, a second reflective structure 120a may include an organic material 125 and particles 126. The organic material 125 may be transparent. A refractive index of the organic material 125 may be different from that of the transparent substrate 300. Thus light may be reflected at an interface between the organic material 125 and the transparent substrate 300. The particles 126 may be dispersed in the organic material 125. A refractive index of the particles 126 may be different from that of the organic material 125, and thus light may be reflected at interfaces between the organic material 125 and the particles 126. For example, the organic material 125 may include resin or silicone, and the particles 126 may include an inorganic material such as SiOₓ, SiCₓ, TiOₓ, HfOₓ, TaₓO_{y}, or SiN (where ‘x’ and ‘y’ are constants). For another example, the particles 126 may include a fluorescent substance.

Referring to FIG. 2B, a second reflective structure 120b may have a distributed Bragg reflective (DBR) structure including first to fourth layers 121, 122, 123 and 124 which are stacked along the first and second directions D1 and D2. A refractive index of the first layer 121 may be different from that of the transparent substrate 300, and thus light may be reflected at an interface between the first layer 121 and the transparent substrate 300. Each of the layers 121 to 124 may have a refractive index different from that or those of other layer(s) adjacent thereto. For example, the refractive index of the second layer 122 may be different from that of the first layer 121. Thus, light may be reflected at an interface between the first and second layers 121 and 122. The refractive index of the third layer 123 may be different from those of the second and fourth layers 122 and 124, and thus light may be reflected at an interface between the second and third layers 122 and 123 and an interface between the third and fourth layers 123 and 124. Thus, the second reflective structure 120 may have high reflection efficiency. The number of the layers 121 to 124 is not limited to the embodiment of FIG. 2B and may be variously changed.

Referring to FIGS. 2C and 2D, the shape of the second reflective structure 120 may be variously modified. For example, a second reflective structure 120d may have a triangular cross section. as illustrated in FIG. 2C, e.g., may be inclined such that the sidewalls thereof meet, or a second reflective structure 120e may have a quadrilateral cross section, as illustrated in FIG. 2D, e.g., sidewalls 301c′. may form a right angle with the first surface of the transparent substrate 300. However, the shape of the second reflective structure is not limited to the embodiments of FIGS. 2C and 2D and may be variously modified.

Referring again to FIGS. 1A and 1B, the second reflective structure 120 may surround the light emitting device 200 when viewed in a plan view. The second reflective structure 120 may have a closed-loop shape in a plan view. In some embodiments, the second reflective structure 120 may be provided in plurality. The second reflective structures 120 may be spaced apart from each other.

The second reflective structures 120 and the first reflective structure 110 may be formed by the same process. In this case, the second reflective structures 120 and the first reflective structure 110 may be formed as a single unitary body. For example, the second reflective structures 120 may include the same material as the first reflective structure 110 and may be connected to the first reflective structure 110. Alternatively, the second reflective structures 120 may be formed by a process different from a process of forming the first reflective structure 110.

If the reflective structure 100 is omitted, a portion of the light generated from the light emitting device 200 may be emitted to the outside through a sidewall of the transparent substrate 300. In other words, light may be emitted from a sidewall of the light emitting package 1. However, according to some embodiments, the reflective structure 100 (e.g., the second reflective structure(s) 120) may reflect the light, emitted from the sidewalls 200c of the light emitting device 200, toward the top surface of the light emitting package 1. Thus, the light extraction efficiency (or luminous efficiency) of the light emitting package 1 may be improved.

A fluorescent layer 410 may be on the top surface 300a of the transparent substrate 300. The top surface 300a of the transparent substrate 300 may be opposite to the bottom surface 300b thereof. The top surface 300a of the transparent substrate 300 may be flat. The fluorescent layer 410 may include an organic material in which fluorescent substances are dispersed. For example, the fluorescent substances may include yellow fluorescent substances. The light emitting device 200 may generate blue light. The blue light may be emitted to the outside through the fluorescent layer 410. Thus, the light emitting package 1 may emit white light.

FIG. 1D is a cross-sectional view corresponding to the line A-B of FIG. 1A to illustrate a light emitting package according to some embodiments. Hereinafter, for the purpose of ease and convenience in explanation, the descriptions to the same features as in the above embodiments will be omitted or mentioned briefly, and one second reflective structure will be mainly described.

Referring to FIGS. 1A and 1D, a light emitting package 2 may include the light emitting device 200, the transparent substrate 300, the fluorescent layer 410, and a reflective structure 100a including a first reflective structure 110a and the second reflective structure 120. The light emitting device 200, the transparent substrate 300, the fluorescent layer 410, and the second reflective structure 120 may be substantially the same as described with reference to FIGS. 1A to 1C. The first reflective structure 110a may not extend onto the bottom surface 200b of the light emitting device 200, e.g., a bottom surface of the first reflective structure 110a may be coplanar with the bottom surface 200b. For example, the first reflective structure 110a may include the organic material and the particles dispersed in the organic material or may include the plurality of layers. Alternatively, the first reflective structure 110 may include a metal such as silver (Ag) or aluminum (Al).

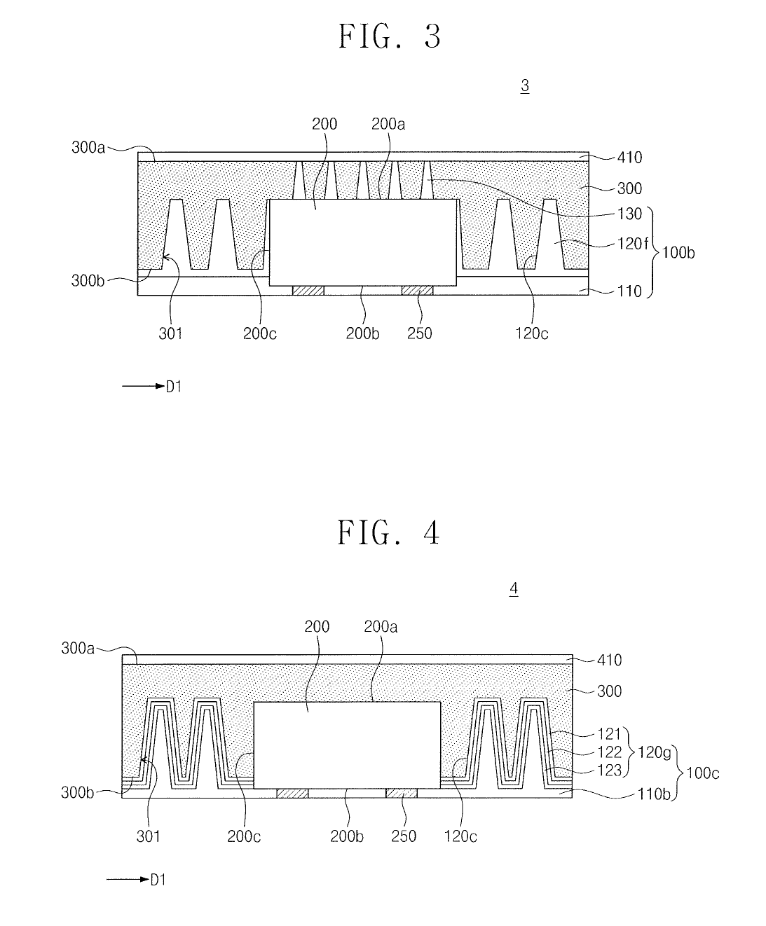

FIG. 3 is a cross-sectional view corresponding to the line A-B of FIG. 1A to illustrate a light emitting package according to some embodiments. Hereinafter, the descriptions to the same features as in the above embodiments will be omitted or mentioned briefly.

Referring to FIGS. 1A and 3, a light emitting package 3 may include the light emitting device 200, the transparent substrate 300, the fluorescent layer 410, and a reflective structure 100b including a first reflective structure 110, a second reflective structure 120f, and a third reflective structure 130. The light emitting device 200, the transparent substrate 300, the fluorescent layer 410, and the first reflective structure 110 may be substantially the same as described above. In some embodiments, a trench 301 may extend from a first surface of the transparent substrate 300 into the transparent substrate 300. The first surface of the transparent substrate 300 may be the bottom surface 300b of the transparent substrate 300.

The second reflective structure 120 may extend along a top surface of the first reflective structure 110 and the bottom surface 300b of the transparent substrate 300. In other words, the second reflective structure 120 may be between the top surface of the first reflective structure 110 and the bottom surface 300b of the transparent substrate 300 to cover the bottom surface 300b of the transparent substrate 300. The second reflective structure 120f may include a protruding portion. The protruding portion of the second reflective structure 120f may be provided in the trench 301 of the transparent substrate 300. The protruding portion of the second reflective structure 120f may be substantially the same as the second reflective structure 120 described with reference to FIGS. 1A to 1C. The protruding portion of the second reflective structure 120 may be disposed on the extending portion of the second reflective structure 120. The protruding portion of the second reflective structure 120 may be provided in plurality. The protruding portions of the second reflective structure 120 may be connected to each other by the extending portion of the second reflective structure 120. The second reflective structure 120 may further extend along the sidewalls 200c of the light emitting device 200 on the top surface of the first reflective structure 110. In certain embodiments, unlike FIG. 3, the first reflective structure 110 may be omitted.

The third reflective structure 130 may further be on the top surface 200a of the light emitting device 200. The third reflective structure 130 may have a refractive index different from that of the transparent substrate 300. The third reflective structure 130 may include at least one of the materials and shapes described as the examples of the second reflective structure 120.

FIG. 4 is a cross-sectional view illustrating a light emitting package according to some embodiments. Hereinafter, the descriptions to the same features as in the above embodiments will be omitted or mentioned briefly.

Referring to FIG. 4, a light emitting package 4 may include the light emitting device 200, the transparent substrate 300, the fluorescent layer 410, and a reflective structure 100c that includes a first reflective structure 110b and a second reflective structure 120g. The first reflective structure 110b may include a protruding portion. The second reflective structure 120g may be provided in the trench 301 and may extend along the bottom surface 300b of the transparent substrate 300. The second reflective structure 120g may include a plurality of layers 121, 122 and 123. First, second, and third layers 121, 122 and 123 may be stacked on the first reflective structure 110b. The protruding portion of the first reflective structure 110 may be provided in the trench 301. Adjacent ones of the layers 121, 122 and 123 may have different refractive indexes. The layers 121, 122, and 123 of the second reflective structure 120 may be substantially the same as the first to third layers 121, 122, and 123 described with reference to FIG. 2B. The first layer 121 may have a refractive index different from that of the transparent substrate 300. The third layer 123 may have a refractive index different from that of the first reflective structure 110. The number of the layers 121 to 123 is not limited to the embodiment of FIG. 4 and may be variously changed.

FIG. 5 is a cross-sectional view illustrating a light emitting package according to some embodiments. Hereinafter, the descriptions to the same features as in the above embodiments will be omitted or mentioned briefly.

Referring to FIG. 5. a light emitting package 5 may include the light emitting device 200, the transparent substrate 300. the fluorescent layer 410, and a reflective structure 100d that includes the first reflective structure 110 and a second reflective structure 120h. The first reflective structure 110 may be provided on the bottom surface 300b of the transparent substrate 300.

A trench 301 may extend from a first surface of the transparent substrate 300 into the transparent substrate 300. Here, the first surface may be the top surface 300a of the transparent substrate 300. The second reflective structure 120h may be provided in the trench 301. The second reflective structure 120 may extend onto the top surface 300a of the transparent substrate 300. Alternatively, the second reflective structure 120h may not extend onto the top surface 300a of the transparent substrate 300. In this case, the second reflective structure 120h may include a plurality of second reflective structures 120h separated from each other, as shown in FIG. 1B. The second reflective structures 120 may be cavities defined by the transparent substrate 300 and the fluorescent layer 410. The second reflective structures 120 may include at least one of the materials described with reference to FIGS. 1A to 2B. The fluorescent layer 410 may be provided on a top surface of the second reflective structure 120.

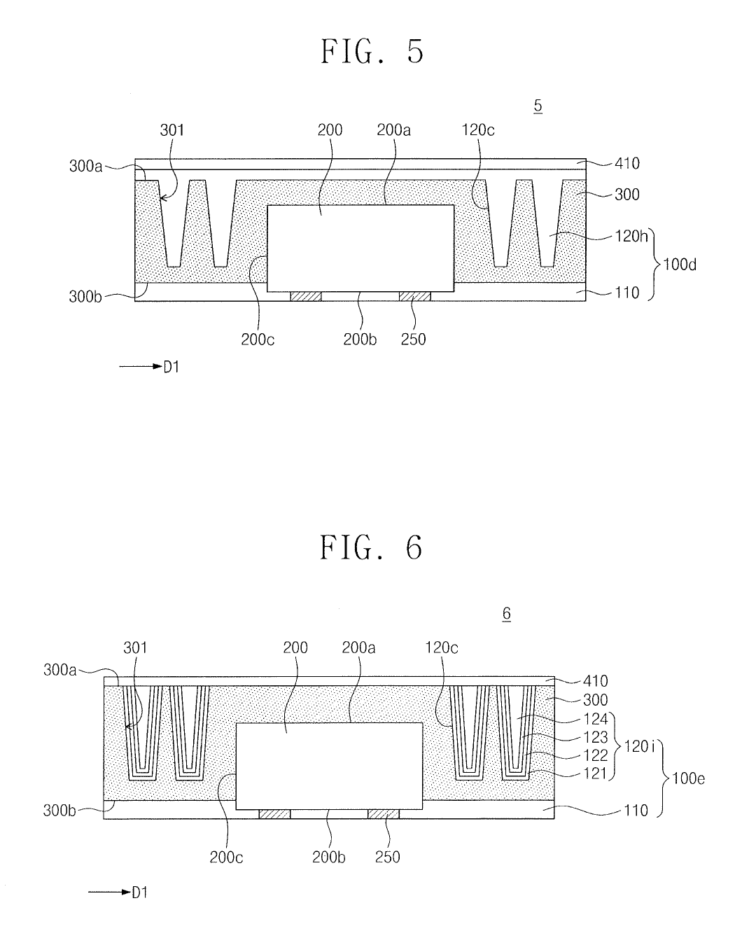

FIG. 6 is a cross-sectional view illustrating a light emitting package according to some embodiments. Hereinafter, the descriptions to the same features as in the above embodiments will be omitted or mentioned briefly.

Referring to FIG. 6, a light emitting package 6 may include the light emitting device 200, the transparent substrate 300, the fluorescent layer 410, and a reflective structure 100e that includes the first reflective structure 110 and a second reflective structure 120i. The first reflective structure 110 may be provided on the bottom surface 300b of the transparent substrate 300. A trench 301 may extend from the top surface 300a of the transparent substrate 300 into the transparent substrate 300. The second reflective structure 120i may be provided in the trench 301 of the transparent substrate 300. An inclined sidewall 120c of the second reflective structure 120i may be covered by the transparent substrate 300. Alternatively, the second reflective structure 120i may not extend onto the top surface 300a of the transparent substrate 300. The second reflective structure 120 may include a plurality of second reflective structures 120 separated from each other. Each of the second reflective structures 120 may include first to fourth layers 121, 122, 123, and 124.

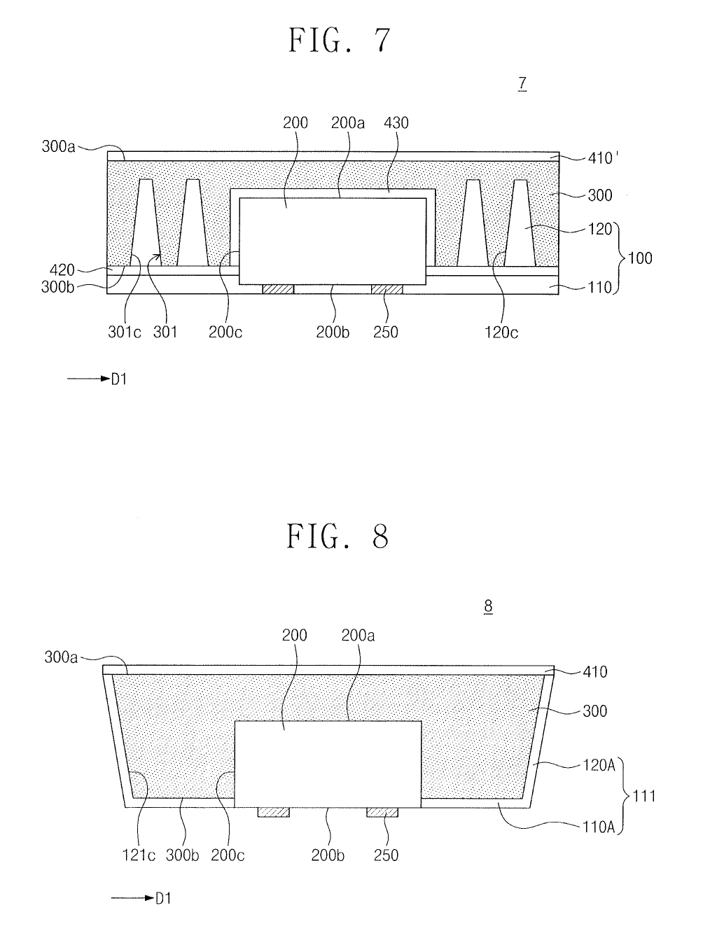

FIG. 7 is a cross-sectional view corresponding to the line A-B of FIG. 1A to illustrate a light emitting package according to some embodiments. Hereinafter, the descriptions to the same features as in the above embodiments will be omitted or mentioned briefly.

Referring to FIG. 7, a light emitting package 7 may include the light emitting device 200, the transparent substrate 300, the first reflective structure 110, the second reflective structure 120, a first fluorescent layer 410′, a second fluorescent layer 420, and a third fluorescent layer 430. The first fluorescent layer 410′ may be the same as the fluorescent layer 410 of FIGS. 1A and 1B. For example, the first fluorescent layer 410′ may be on the top surface 300a of the transparent substrate 300. The second fluorescent layer 420 may be on the bottom surface 300b of the transparent substrate 300. The second fluorescent layer 420 may be between the first reflective structure 110 and the second reflective structure 120. The third fluorescent layer 430 may extend along the sidewalls 200c and the top surface 200a of the light emitting device 200. The third fluorescent layer 430 may be between the light emitting device 200 and the transparent substrate 300. The second and third fluorescent layers 420 and 430 may include the same material as the fluorescent layer 410 of FIGS. 1A and 1B and may have substantially the same function as the fluorescent layer 410 of FIGS. 1A and 1B. For example, each of the second and third fluorescent layers 420 and 430 may include an organic material in which fluorescent substances are dispersed.

In certain embodiments, one of the first to third fluorescent layers 410′, 420, and 430 may be omitted. The positions and arrangement of the fluorescent layers 410′, 420, and 430 are not limited to the embodiment of FIG. 7 and may be variously modified. In certain embodiments, the first to third fluorescent layers 410′, 420 and 430 may be omitted, and the fluorescent substances may be dispersed in the transparent substrate 300. In certain embodiments, the first to third fluorescent layers 410′, 420 and 430 may be omitted, and the fluorescent substances may be provided in the first reflective structure 110 or the second reflective structure 120.

FIG. 8 illustrates a cross-sectional view of a light emitting package according to some embodiments. Hereinafter, the descriptions to the same features as in the above embodiments will be omitted or mentioned briefly.

Referring to FIG. 8, a light emitting package 8 may include the light emitting device 200, the transparent substrate 300, the fluorescent layer 410, and a first reflective structure 111. The first reflective structure 111 may include a first portion 110A and a second portion 120A. The first portion 110A of the first reflective structure 111 may be on the bottom surface 300b of the transparent substrate 300. The second portion 120A of the first reflective structure 111 may be provided on sidewalls 300c of the transparent substrate 300. The second portion 120A of the first reflective structure 111 may be connected to the first portion 110A of the first reflective structure 111, e.g., the first reflective structure may be integrated. The second portion 120A of the first reflective structure 111 may have a sidewall 121c. The sidewall 121c of the second portion 120A of the first reflective structure 111 may be inclined with respect to the bottom surface 300b of the transparent substrate 300. The first reflective structure 111 may include the same material as the first reflective structure 110 of FIGS. 1A to 1C or the second reflective structure 120 of FIG. 2A or 2B. For example, the first reflective structure 111 may include the organic material in which the particles are dispersed, or the plurality of layers. Alternatively, the first reflective structure 111 may include a metal. The transparent substrate 300 may cover the sidewall 121c of the first reflective structure 111. The first reflective structure 111 may have a refractive index different from that of the transparent substrate 300, and thus light may be reflected toward a top surface of the light emitting package 8 by the first reflective structure 111.

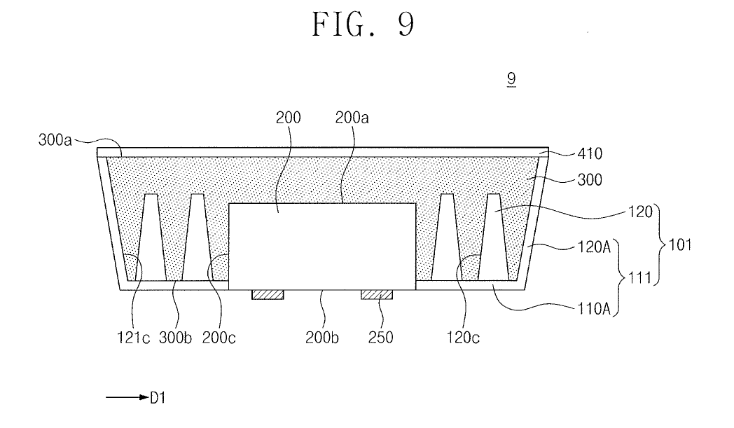

FIG. 9 illustrates a cross-sectional view of a light emitting package according to some embodiments. Hereinafter, the descriptions to the same features as in the above embodiments will be omitted or mentioned briefly.

Referring to FIG. 9, a light emitting package 9 may include the light emitting device 200, a transparent substrate 300. a fluorescent layer 410, and a reflective structure 101. The reflective structure 101 may include the first reflective structure 111 and a second reflective structure 120. The first reflective structure 111 may be substantially the same as the first reflective structure 111 described with reference to FIG. 8. The second reflective structure 120 may be on the first reflective structure 111, e.g., a first portion 110A. The second reflective structure 120 may be substantially the same as any one of the second reflective structures 120 described with reference to FIGS. 1A to 4. For example, the second reflective structure 120 may be provided in a trench extending from the bottom surface 300b of the transparent substrate 300 into the transparent substrate 300. Alternatively, the trench may extend from the top surface 300a of the transparent substrate 300 into the transparent substrate 300, as described with reference to FIGS. 5 and 6.

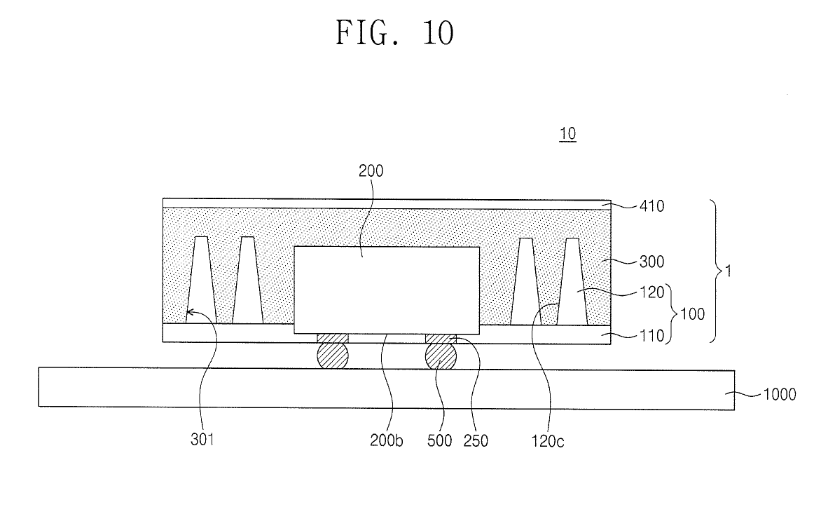

FIG. 10 illustrates a cross-sectional view of a light emitting apparatus according to some embodiments. Hereinafter, the descriptions to the same features as in the above embodiments will be omitted or mentioned briefly.

Referring to FIG. 10, a light emitting apparatus 10 may include a circuit substrate 1000 and a light emitting package 1. For example, the circuit substrate 1000 may include a printed circuit board (PCB) having a circuit pattern. The light emitting package 1 may be mounted on the circuit substrate 1000. The light emitting package 1 may be the same as described with reference to FIGS. 1A and 1B. The electrode 250 may be exposed on the bottom surface of the light emitting package 1. The light emitting package 1 may be disposed on the circuit substrate 1000 in such a way that the bottom surface 200b of the light emitting device 200 faces the circuit substrate 1000, and a connection terminal 500 may be formed between the electrode 250 and the circuit substrate 1000. For example, the connection terminal 500 may include a bump or a solder ball. The light emitting package 1 may not include an additional package substrate provided on the bottom surface 200b of the light emitting device 200. Since the package substrate is not disposed between the circuit substrate 1000 and the light emitting device 200, a size of the light emitting apparatus 10 may be reduced or minimized. In certain embodiments, at least one of the light emitting packages 2, 3, 4, 5, 6, 7, 8 and 9 described with reference to FIGS. 1D and 3 to 9 may be mounted on the circuit substrate 1000.

According to some embodiments, the reflective structure may be provided on, e.g., adjacent, the sidewall of the light emitting device. The reflective structure may reflect light emitted from the sidewall of the light emitting device to the top surface of the light emitting package. Thus, the light extraction efficiency of the light emitting package may be improved.

In addition, the electrode of the light emitting device may be exposed at the bottom surface of the light emitting package. Thus, it is possible to reduce or minimize the sizes of the light emitting package and the light emitting apparatus including the light emitting package.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features. characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A light emitting package, comprising:
a light emitting device having an electrode on a bottom surface;
a transparent substrate covering a top surface and sidewalls of the light emitting device; and
a reflective structure adjacent sidewalls of the light emitting device,
wherein the reflective structure has a refractive index different from that of the transparent substrate, and
wherein the electrode is exposed by the transparent substrate and the reflective structure.

2. The light emitting package as claimed in claim 1, wherein the reflective structure includes:
a first reflective structure on a bottom surface of the transparent substrate; and
a second reflective structure extending into the transparent substrate adjacent the sidewalls of the light emitting device, the second reflective structure having inclined sidewalls.

3. The light emitting package as claimed in claim 2, further comprising:
a fluorescent layer extending along a top surface of the first reflective structure,
wherein the fluorescent layer is between the first reflective structure and the second reflective structure.

4. The light emitting package as claimed in claim 2, wherein:
the second reflective structure is provided in a trench extending from a top surface of the transparent substrate into the transparent substrate, and
the top surface of the transparent substrate is opposite to the bottom surface of the transparent substrate.

5. The light emitting package as claimed in claim 4, further comprising:
a fluorescent layer on the transparent substrate,
wherein the second reflective structure is disposed between the transparent substrate and the fluorescent layer.

6. The light emitting package as claimed in claim 2, wherein:
the second reflective structure is provided in a trench extending from the bottom surface of the transparent substrate into the transparent substrate, and
the second reflective structure is on the first reflective structure.

7. The light emitting package as claimed in claim 1, wherein the reflective structure includes:
a first layer; and
a second layer stacked on the first layer and having a refractive index different from that of the first layer.

8. The light emitting package as claimed in claim 1, wherein:
the reflective structure includes an organic material having particles dispersed therein, and
the particles have a refractive index different from that of the organic material.

9. The light emitting package as claimed in claim 1, wherein the reflective structure includes an organic material having fluorescent particles dispersed therein.

10. The light emitting package as claimed in claim 1, wherein the reflective structure is a cavity defined in the transparent substrate.

11. The light emitting package as claimed in claim 1, wherein the reflective structure surrounds the light emitting device when viewed in a plan view.

12. The light emitting package as claimed in claim 1, wherein:
the light emitting device includes a first semiconductor layer, an active layer, and a second semiconductor layer, and
the electrode is electrically connected to one of the first semiconductor layer and the second semiconductor layer.

13. The light emitting package as claimed in claim 1, wherein the transparent substrate has inclined sidewalls and the reflective structure extends along a bottom surface of the transparent substrate and the inclined sidewalls of the transparent substrate.

14. A light emitting package, comprising:
a light emitting device including an electrode provided on a bottom;
a transparent substrate covering a top surface and sidewalls of the light emitting device and having a trench extending from a first surface of the transparent substrate into the transparent substrate, wherein the trench has a sidewall inclined with respect to the first surface of the transparent substrate; and
a reflective structure provided in the trench and having a refractive index different from that of the transparent substrate,
wherein the reflective structure is on the sidewall of the light emitting device, and
wherein the electrode is exposed by the reflective structure.

15. The light emitting package as claimed in claim 14, wherein the reflective structure further extends along the first surface of the transparent substrate.

16. The light emitting package as claimed in claim 14, wherein:
the reflective structure includes a plurality of stacked layers, and
adjacent ones of the stacked layers have different refractive indexes from each other.

17. The light emitting package as claimed in claim 14, further comprising a fluorescent layer on the first surface of the transparent substrate and covering the reflective structure.
